(19) United States
(12) Patent Application Publication
(10) Pub. No.: US 2010/0112788 A1
(43) Pub. Date: May 6, 2010

(54) METHOD TO REDUCE SURFACE DAMAGE AND DEFECTS

(76) Inventor: Deepak Ramappa, Cambridge, MA (US)

Correspondence Address: Nields, Lemack & Frame, LLC, 176 E. MAIN STREET, SUITE 5, WESTBOROUGH, MA, 01581, US

(21) Appl. No.: 12/603,774

(22) Filed: Oct. 22, 2009

Related U.S. Application Data
(60) Provisional application No. 61/110,007, filed on Oct. 31, 2008.

(51) Int. Cl. H01L 21/302; H01L 21/3205

(52) U.S. Cl. 438/473; 438/682; 257/E21.214; 257/E21.296

(57) ABSTRACT

A method of implantation that minimizes surface damage to a workpiece is disclosed. In one embodiment, following a doping implant, a second implant is performed which causes the silicon at the surface of the workpiece to become amorphous. This reduces surface damage and interstitials, which has several benefits. First, inactive dopant clusters may become activated due to the replenishment of silicon. Secondly, the amorphous nature of the silicon makes it bond more easily in subsequent process steps, such as silicidation.

This application claims priority to U.S. Provisional Patent Application No. 61/110,007, filed Oct. 31, 2008, the disclosure of which is herein incorporated by reference in its entirety.

### FIELD

This disclosure relates to the implantation of species, and more particularly to the implantation of species to prevent surface damage or repair surface damage.

### BACKGROUND

Ion implantation is a standard technique for introducing conductivity-altering impurities into semiconductor workpieces. A desired impurity material is ionized in an ion source, the ions are directed at the surface of the workpiece. The energetic ions penetrate into the bulk of the semiconductor material and are embedded into the crystalline lattice of the semiconductor material to form a region of desired conductivity.

The implantation of dopants is known to create defects in the semiconductor workpiece. This damage may cause interstitials or vacancies that affect the conductivity of the workpiece. Previously, the damaged areas were a small percentage of the total junction regions, and therefore had little effect on the overall performance of the semiconductor device.

However, junctions in integrated circuits (IC) have become shallower as devices have been scaled down. As junctions become shallower, the volume of the junction occupied by the dopant likewise shrinks. Efficient activation of this small volume of dopant is a challenge. Furthermore, surface damage caused by ion implantation that may have been considered negligible for previous technology nodes or larger size ICs now has gained importance. Since junctions have become shallower, damage depths have become approximately 10-30% of the junction depth at 32 nm high power laser annealing (HPL).

In addition, inactive dopant clusters at the surface of the junction also have increased as junctions have shrunk. These inactive areas are caused by silicon vacancy clusters, or the lack of silicon in the area due to sputtered off silicon. Inactive dopant clusters result in poor dopant activation, which will increase source-drain (S/D) resistance of a transistor. Therefore, not only does the small volume of dopant pose a challenge during activation, but this is further impeded by poor dopant activation.

Surface damage that is not completely removed during an anneal can be detrimental to IC performance. FIG. 1 is a transmission electron microscope (TEM) image of surface damage on a sample after an ion implant and anneal cycle. The dark regions show areas of damage to the workpiece. Silicon vacancies that resulted from the ion implantation create a rough or non-planar interface for a later silicide process.

Silicides are often used in ICs to reduce resistance because silicides have a lower resistance than polysilicon.

These silicides may be formed on an IC to create, for example, the ohmic contacts of the source, drain, or gate. In some embodiments, metals are deposited on the IC, such as through sputtering. The metal combines with the silicon on the surface of a workpiece. The metal atoms will become the metal component of the silicide in a chemical reaction during the annealing step. The metal component may be, for example, nickel, tungsten, cobalt, or titanium.

A rough or non-planar surface on the workpiece leads to contact leakage after the silicide formation because the unsilicided metals will diffuse into the silicon of the workpiece, forming spikes or, as it is sometimes called, silicide pitting. FIG. 2 is a TEM image of metal-silicide spiking. If an excess density of vacancies is present, spiking may occur. Ideally, the metal reacts with the silicon to form a stable silicide. Once this stable phase is created, the metal is bonded to the silicon and held back from diffusing. If vacancies or interstitials are present at the reacting surface of the silicon, however, the metal will have higher diffusivity than the silicon. The activation energy of formation of silicide is higher than the diffusing activation energy, leading to more diffusivity or making it easier for the metal to diffuse than bond. The tendency to diffuse is based on chemical properties of each metal, and increases from tungsten to titanium to cobalt to nickel. Therefore, if a stacking fault (i.e., multiple vacancies) is present, nickel will diffuse down the stacking fault to form a “silicide pipe.” Nickel or other metals will diffuse in this direction because this is the 3-1-1 plane and because 1-0-0 silicon has the highest tendency to form stacking faults.

Note that the spikes shown in FIG. 2 display a diagonal pattern, because of the tendency for the metals to diffuse at roughly a 45° angle with respect to the workpiece surface. Ideally, each metal atom combines with one or more silicon atoms to form the desired silicide. Surface damage and silicon vacancies lead to silicon atoms with varying numbers of unbonded electrons existing within the workpiece. This may lead to the formation of a different and perhaps undesirable phase of silicide. For example, nickel silicides having the formula NiₓSi_{y} may be formed that may further increase contact resistance. For example, the desired phase may be NiSi and, instead, Ni₂Si and Ni₃Si may form, although other desired phases and undesired phases are possible. These undesired phases typically are not as stable as the desired phases and also typically have a higher resistance.

Dose rate is one factor that increases surface damage of an integrated circuit. A higher beam current will increase surface damage or increase defects. This may lead to damage, dopant activation, or silicidation problems. Reducing beam currents, however, is undesirable because it reduces the throughput of the implant process. Accordingly, there is a need for an improved method to prevent surface damage or repair surface damage.

### SUMMARY

A method of implantation is disclosed which minimizes surface damage to a workpiece. Following a doping implant, a second implant is performed which causes the silicon at the surface of the workpiece to become amorphous. This reduces surface damage and interstitials, which has several benefits. First, inactive dopant clusters may become activated due to the replenishment of silicon. Secondly, the amorphous nature of the silicon makes it bond more easily in subsequent process steps, such as silicidation.

In some embodiments, a dopant is implanted and then annealed prior to the amorphizing implant. In other embodiments, the anneal is performed after the amorphizing implant. In yet other embodiments, an amorphizing implant is perform both before and after the anneal cycle. Additionally, a pre-amorphization implant (PAI) may be performed prior to the dopant implantation.

### BRIEF DESCRIPTION OF THE DRAWINGS

For a better understanding of the present disclosure, reference is made to the accompanying drawings, in which like elements are referenced with like numerals, and in which:

FIG. 1 is a TEM image of surface damage on a sample after implant and anneal;

FIG. 2 is a TEM image of metal-silicide spiking; FIG. 3A-3B are flowcharts for a first embodiment of a method to prevent or repair surface damage;

FIGS. 4A-4B are flowcharts for a second embodiment of a method to prevent or repair surface damage;

FIGS. 5A-5D are charts illustrating secondary ion mass spectrometry (SIMS) profiles with a damage reduction implant, in accordance with the method of FIG. 3A;

FIGS. 6A-6D are charts illustrating secondary ion mass spectrometry (SIMS) profiles with a damage reduction implant, in accordance with the method of FIG. 3B;

FIG. 7 is a block diagram of a plasma doping system; and FIG. 8 is a block diagram of a beamline ion implanter.

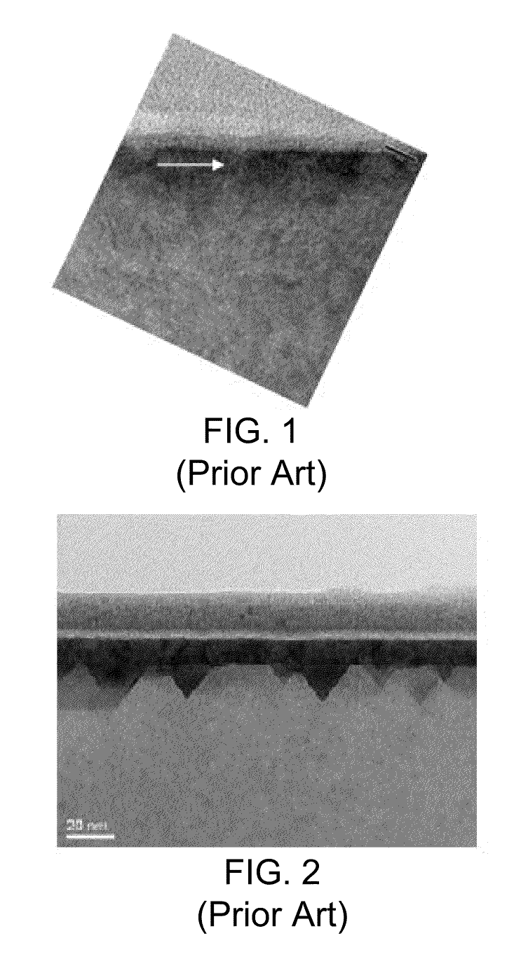

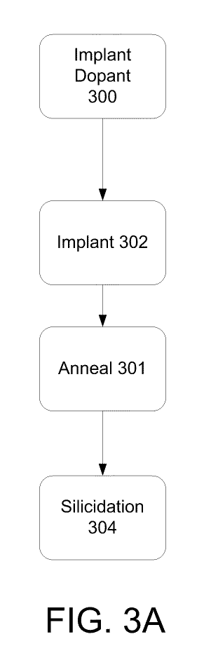

### DETAILED DESCRIPTION

FIG. 3A is a flowchart for a first embodiment of a method to prevent or repair surface damage. A dopant is implanted 300 into a workpiece. Dopants are well known and include B, P, N, As and others. An implant 302 is performed prior to the activation anneal 301 to prevent surface damage. Implant 302 may be a low-energy, non-doping implant that amorphizes the surface of the IC. Amorphizing the surface will destroy or change the long-range order of the crystal lattice in the workpiece. Non-doping species such as C, Si, Ge, Sn, or Pb may be used to amorphize the workpiece. Doping species like B, P, or N also may be used. All of these species are preferably implanted at doses above the amorphization threshold of each. In another embodiment, these species are used as co-dopants with the non-doping species mentioned above. In some embodiments, implant 300 and 302 may be performed sequentially, while in other embodiments, they are performed at least partially simultaneously. After the surface has been amorphized, an activation anneal 301 is performed. The activation anneal can be an RTA, spike, flash or laser anneal (millisecond/melt) in the temperature range between 850° C. and 1150° C., depending on the species used. This is followed by silicidation 304.

In another example, shown in FIG. 3B, an activation anneal 301 is performed after the dopant implant 300. Subsequently, an implant 303 is performed after the activation anneal 301 to repair surface damage. As described above, implant 303 may be a low-energy, non-doping implant that amorphizes the surface of the IC. Amorphizing the surface will destroy or change the long-range order of the crystal lattice in the workpiece. Non-doping species such as C, Si, Ge, Sn, or Pb may be used to amorphize the workpiece. Doping species like B, P, or N also may be used. All of these species are implanted at doses above the amorphization threshold of each. In another instance, these species are used as co-dopants with the non-doping species mentioned above. In some embodiments, implanting of doping and non-doping species is performed at least partially simultaneously. This is followed by silicidation 304.

Either implant 302 or implant 303 will amorphize any vacancies and may replenish the silicon at surface of the workpiece. Thus, silicon will be spread or disposed more evenly so that no vacancies exist. Amorphization of the non-active dopant volume at the surface of the workpiece will improve activation and, consequently, reduce resistance. Activation is improved because the amorphization may place the dopants more evenly within the silicon crystal lattice and enable further activation of any inactive dopant clusters that may exist. Furthermore, the dopant profile may be modified. Surface roughness of the IC may be reduced through implant 302 or implant 303 when the crystal lattice is amorphized and any voids or vacancies are replenished with silicon.

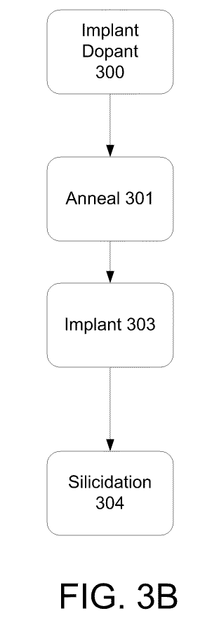

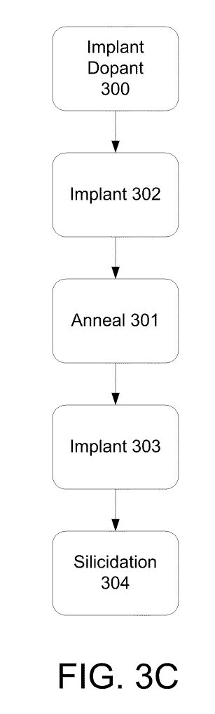

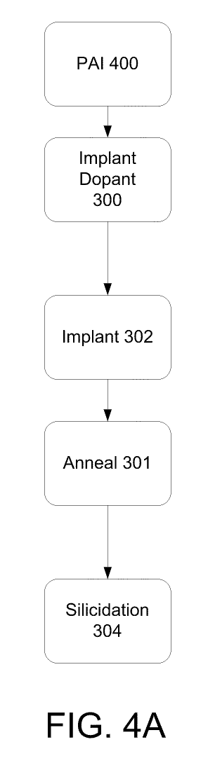

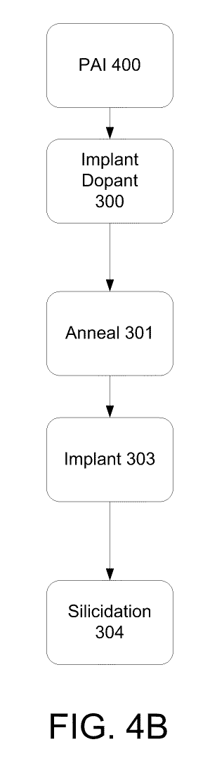

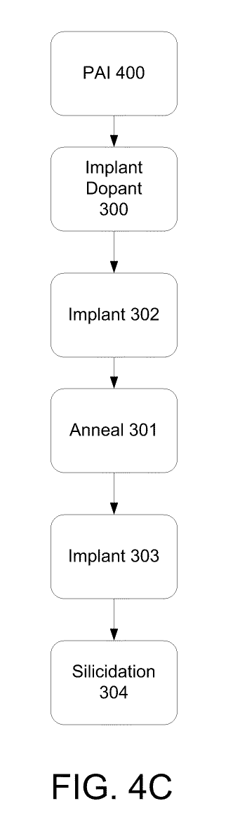

FIG. 4A is a flowchart for another embodiment of a method to prevent or repair surface damage. Prior to the dopant being implanted 300 into a workpiece, a PAI 400 is performed. Typical PAI implants can be performed with Si, Ge or other amorphizing species with energies chosen to achieve the desired junction depths. The depth of the PAI implants are typically chosen to be slightly (10-20%) higher than the dopant species that follows the PAI implant). This PAI 400 may amorphize the crystal lattice in the workpiece. Following the PAI 400, the sequence of steps described in FIG. 3A is followed.

FIG. 4B is a flowchart of another embodiment of a method to prevent or repair surface damage. This method begins with a PAI 400, and then follows the steps shown in FIG. 3B.

In the embodiments of FIG. 3B and FIG. 4B, implant 303 is performed after the anneal 301. No further activation anneal is required prior to silicidation 304 after the implant 303. The implant 303 will amorphize the crystal lattice of the IC. This will help improve uniformity of the silicidation and may reduce metal (i.e.nickel) diffusion. Silicon consumption deep in the S/D and contact resistivity are reduced. Finally, this improves silicide phase uniformity and the formation of the desired phases of silicide, such as NiSi. This improvement is mainly due to the fact that amorphizing the crystal destroys the long range order of the crystal. This reduces the nickel or metal diffusion into the bulk silicon material, and therefore reduces spiking. When spiking occurs, there is loss of nickel into Si bulk and therefore the ratio of metal to silicon is not as expected, and this skewed ratio drives formation of different phases of silicide. Further, the metal diffusion channels tend to be non-uniformly distributed within the S/D area. Therefore, those areas with a surplus of metal tend to form a metal rich phase. Conversely, the other areas of the silicon tend to form a silicon rich form of silicide.

In alternate embodiments, shown in FIG. 3C and FIG. 4C, an implant 302 is performed prior to the anneal 301 and a second implant 303 is performed after the anneal 301. Although more expensive due to higher number of implants and process steps, the processes represented by FIG. 3C and 4C may enable a much more reliable device with respect to its silicided area performance. Reliability parameters, such as IDDQ current densities, will tend to be lower as the devices tend to be more robust with better long term reliability.

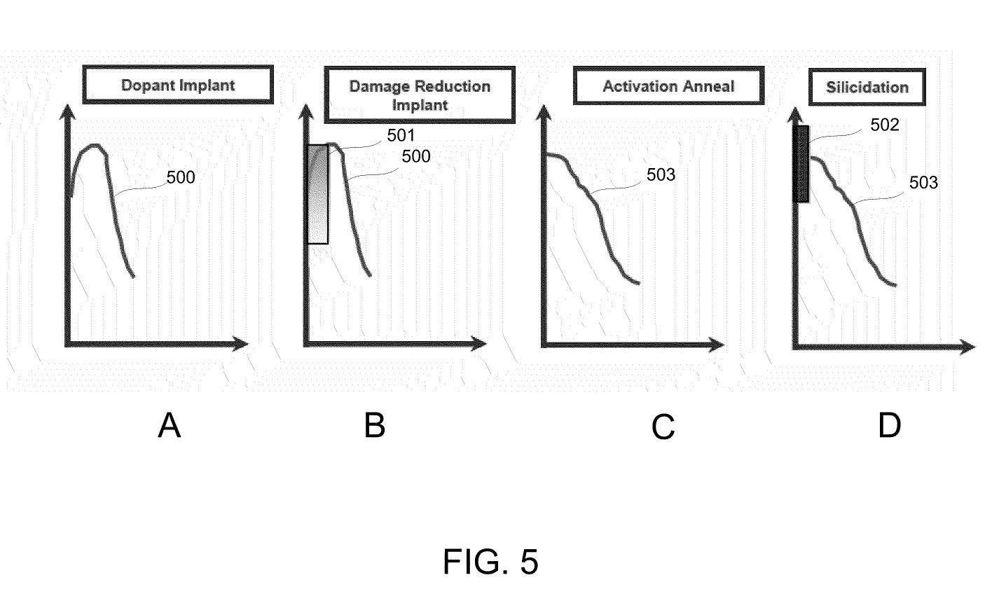

FIGS. 5A-5D are charts illustrating SIMS profiles with a damage reduction implant, as shown in FIG. 3A. In FIG. 5A, the doping implant corresponding to implanting dopant 300 is illustrated with the resulting dopant profile 500. In FIG. 5B, an amorphization implant (i.e. an implant to reduce damage) corresponding to implant 302 is illustrated near the surface of the workpiece in the shaded region 501. In FIG. 5C, the workpiece is annealed, which causes a change in the doping profile 503. In FIG. 5D, the silicidation is illustrated in the shaded region 502 on the amorphized region 501 in the workpiece. As illustrated in FIGS. 5A-5D, the dopant profiles 500, 503 may be modified through amorphization. Other modifications to the dopant profile are possible and the dopant profile 500 is not limited solely to that illustrated in FIGS. 5A-5D.

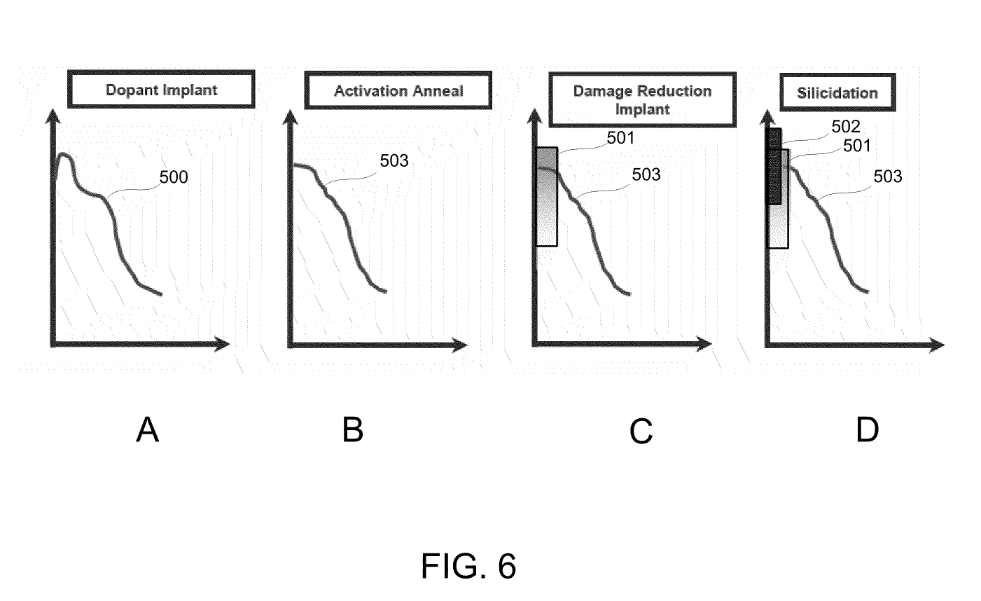

For example, FIGS. 6A-D show the SIMS profiles with a damage reduction implant, as shown in FIG. 3B. In FIG. 6A, the doping implant corresponding to implanting dopant 300 is illustrated with the resulting dopant profile 500. In FIG. 6B, the workpiece is annealed, which causes a change in the doping profile 503. In FIG. 6C, an amorphization implant (i.e. an implant to reduce damage) corresponding to implant 303 is illustrated near the surface of the workpiece in region 501. In FIG. 6D, the silicidation is illustrated in the shaded region 502 on the amorphized region 501 in the workpiece. As illustrated in FIGS. 6A-6D, the dopant profiles 500, 503 may be modified through amorphization.

Use of precise, shallow amorphizing implants will create amorphized silicon at the surface of the workpiece. This will encourage the formation of a silicide with the amorphized silicon. This also may allow formation of a polycide. The amorphization implant of silicon at the surface increases the amount of silicon atoms at the surface of the workpiece. This improves the silicon/dopant ratio in the IC. Furthermore, inactive dopants at the surface of the IC may be reactivated by this replenishment of silicon at the surface of the workpiece. Amorphizing implants also at least partly eliminate the surface damage caused by increased dose. Metal-silicide spiking may be reduced or eliminated.

A cold implant may be beneficial because cooler implants can increase amorphization depth and quality at a lower dose. The temperature range of the cold implant can be anywhere from +60° C. to −300° C. Lower workpiece temperatures lower the threshold where a species can amorphize the workpiece and also may improve the amorphization quality. Amorphization quality is improved at lower temperatures because the crystal lattice of the workpiece may be closer together compared to the crystal lattice at a higher temperature. Lower temperatures also reduce end-of-range (EOR) defects caused by the implant. EOR in a silicon lattice is a plurality of silicon interstitials that have been knocked out to just below the EOR. Cold temperatures lower the amorphization threshold and will increase the amorphization caused by a certain dose of a species. Therefore, more substitutional vacancies are created more uniformly in the crystal lattice down to the EOR. During a later anneal, recrystallization will start at the interstitials at the EOR and will move upward, causing stress and EOR defects. By more thoroughly amorphizing a given area, every interstitial is provided a better opportunity to get back into its substitutional site, thus reducing EOR defects. Cold implants also may lower the required dose to amorphize.

However, in other embodiments, the amorphization implants may be performed at room temperature, or at elevated temperatures, such as 50° C. to 400° C.

Although the implants disclosed are described in conjunction with a subsequent silicidation process, the method can be used with other contacting process steps.

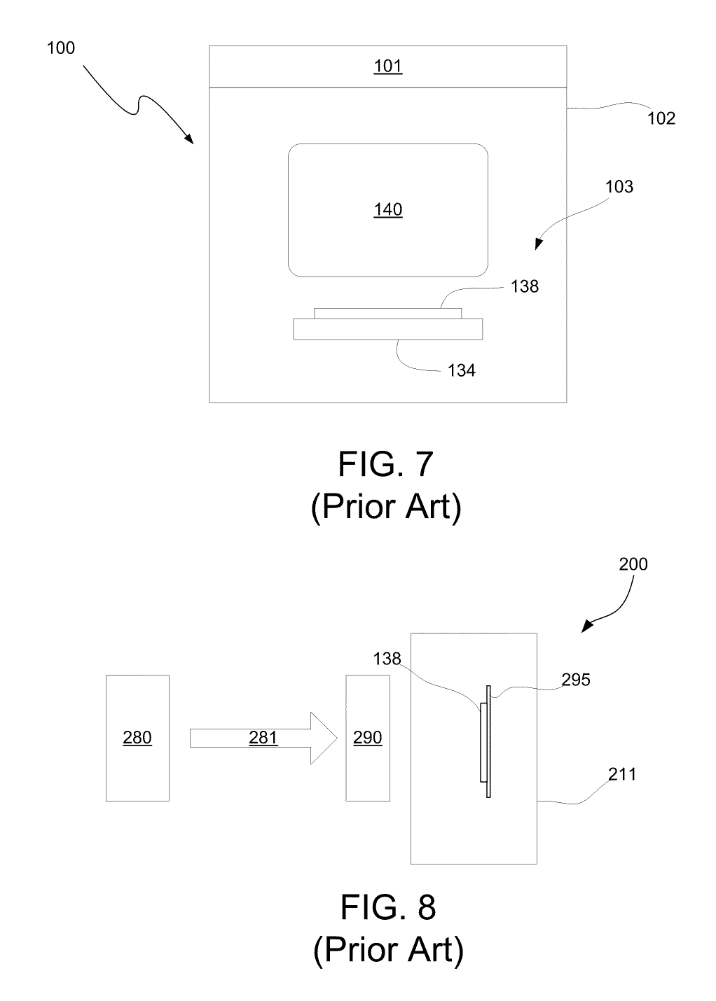

The implants disclosed in the embodiments herein may be performed using either a plasma doping system 100 or a beamline ion implanter 200. FIG. 7 is a block diagram of a plasma doping system 100. FIG. 8 is a block diagram of a beamline ion implanter 200. Those skilled in the art will recognize that the plasma doping system 100 and the beamline ion implanter 200 are each only one of many examples of differing plasma doping systems and beamline ion implanters. Furthermore, those skilled in the art will recognize apparatuses, such as other plasma immersion or plasma flood tools, that also may be used for implanting a species. The implants disclosed in the embodiments herein may be performed using also may be performed in a cluster or stacked configuration tool.

Turning to FIG. 7, the plasma doping system 100 includes a process chamber 102 defining an enclosed volume 103. The process chamber 102 or workpiece 138 may be cooled or heated by a temperature regulation system (not illustrated). A platen 134 may be positioned in the process chamber 102 to support a workpiece 138. The platen 134 also may be cooled or heated by a temperature regulation system (not illustrated). In one instance, the workpiece 138 may be a semiconductor wafer having a disk shape, such as, in one embodiment, a 300 mm diameter silicon wafer. However, the workpiece 138 is not limited to a silicon wafer. The workpiece 138 could also be, for example, a flat panel, solar, or polymer workpiece. The workpiece 138 may be clamped to a flat surface of the platen 134 by electrostatic or mechanical forces. In one embodiment, the platen 134 may include conductive pins (not shown) for making connection to the workpiece 138. The plasma doping system 100 further includes a source 101 configured to generate a plasma 140 from an implant gas within the process chamber 102. The source 101 may be an RF source or other sources known to those skilled in the art. The platen 134 may be biased. This bias may be provided by a DC or RF power supply. The plasma doping system 100 may further include a shield ring, a Faraday sensor, or other components. In some embodiments, the plasma doping system 100 is part of a cluster tool, or operatively-linked plasma doping chambers within a single plasma doping system 100. Thus, numerous plasma doping chambers may be linked in vacuum.

In operation, the source 101 is configured to generate the plasma 140 within the process chamber 102. In one embodiment, the source is an RF source that resonates RF currents in at least one RF antenna to produce an oscillating magnetic field. The oscillating magnetic field induces RF currents into the process chamber 102. The RF currents in the process chamber 102 excite and ionize the implant gas to generate the plasma 140. The bias provided to the platen 134, and, hence, the workpiece 138, will accelerate ions from the plasma 140 toward the workpiece 138 during bias pulse on periods. The frequency of the pulsed platen signal and/or the duty cycle of the pulses may be selected to provide a desired dose rate. The amplitude of the pulsed platen signal may be selected to provide a desired energy. With all other parameters being equal, a greater energy will result in a greater implanted depth.

Turning to FIG. 8, a block diagram of a beamline ion implanter 200 is illustrated. Again, those skilled in the art will recognize that the beamline ion implanter 200 is only one of many examples of beamline ion implanters. In general, the beamline ion implanter 200 includes an ion source 280 to generate ions that are extracted to form an ion beam 281, which may be, for example, a ribbon beam or a spot beam. The ion beam 281 may be mass analyzed and converted from a diverging ion beam to a ribbon ion beam with substantially parallel ion trajectories in one instance. The beamline ion implanter 200 may further include an acceleration or deceleration unit 290 in some embodiments.

An end station 211 supports one or more workpieces, such as workpiece 138, in the path of the ion beam 281 such that ions of the desired species are implanted into workpiece 138. In one instance, the workpiece 138 may be a semiconductor wafer having a disk shape, such as, in one embodiment, a 300 mm diameter silicon wafer. However, the workpiece 138 is not limited to a silicon wafer. The workpiece 138 could also be, for example, a flat panel, solar, or polymer substrate. The end station 211 may include a platen 295 to support the workpiece 138. The end station 211 also may include in one embodiment a scanner (not shown) for moving the workpiece 138 perpendicular to the long dimension of the ion beam 281 cross-section, thereby distributing ions over the entire surface of workpiece 138.

The ion implanter 200 may include additional components known to those skilled in the art such as automated workpiece handling equipment, Faraday sensors, or an electron flood gun. It will be understood to those skilled in the art that the entire path traversed by the ion beam is evacuated during ion implantation. The beamline ion implanter 200 may incorporate hot or cold implantation of ions in some embodiments.

The terms and expressions which have been employed herein are used as terms of description and not of limitation. There is no intention, in the use of such terms and expressions, of excluding any equivalents of the features shown and described (or portions thereof), and it is recognized that various modifications are possible. Other modifications, variations, and alternatives are also possible. Accordingly, the foregoing description is by way of example only and is not intended as limiting.

What is claimed is:

1. A method of reducing surface damage in a workpiece, comprising:
implanting a dopant species into said workpiece;
annealing said workpiece subsequent to said implant; and
performing an amorphizing implant subsequent to said annealing.

2. The method of claim 1, further comprising performing a silicidation step subsequent to said amorphizing implant.

3. The method of claim 2, wherein said silicidication step comprising depositing a metal onto said workpiece, wherein said metal is selected from the group consisting of nickel, titanium, tungsten and cobalt.

4. The method of claim 1, further comprising performing a pre-amorphizing implant step prior to implanting said dopant.

5. The method of claim 4, further comprising performing a silicidation step subsequent to said amorphizing implant.

6. The method of claim 5, wherein said silicidication step comprising depositing a metal onto said workpiece, wherein said metal is selected from the group consisting of nickel, titanium, tungsten and cobalt.

7. The method of claim 1, wherein said amorphizing implant comprises implanting species into said workpiece, wherein said species are selected from the group consisting of carbon, silicon, germanium, tin and lead.

8. The method of claim 1, wherein said amorphizing implant is performed at temperatures between 60° C. and −300° C.

9. A method of reducing surface damage in a workpiece, comprising:
implanting a dopant species into said workpiece;
performing an amorphizing implant subsequent to said implant; and
annealing said workpiece subsequent to said amorphizing implant.

10. The method of claim 9, further comprising performing a second amorphizing implant subsequent to said annealing.

11. The method of claim 9, further comprising performing a silicidation step subsequent to said annealing.

12. The method of claim 11, wherein said silicidication step comprising depositing a metal onto said workpiece, wherein said metal is selected from the group consisting of nickel, titanium, tungsten and cobalt.

13. The method of claim 9, further comprising performing a pre-amorphizing implant step prior to implanting said dopant.

14. The method of claim 13, further comprising performing a silicidation step subsequent to said annealing.

15. The method of claim 14, wherein said silicidication step comprising depositing a metal onto said workpiece, wherein said metal is selected from the group consisting of nickel, titanium, tungsten and cobalt.

16. The method of claim 9, wherein said amorphizing implant comprises implanting species into said workpiece, wherein said species are selected from the group consisting of carbon, silicon, germanium, tin and lead.

17. The method of claim 9, wherein said amorphizing implant is performed at temperatures between 60° C. and −300° C.
